(19) United States
(12) Patent Application Publication
(10) Pub. No.: US 2025/0322863 A1
(43) Pub. Date: Oct. 16, 2025

(54) VOLTAGE CALIBRATION FOR WRITE OPERATION

(71) Applicant: Synopsys, Inc., Sunnyvale, CA (US)

(72) Inventors: Artur Antonyan, San Jose, CA (US); Thuc Nguyen Dinh, Ho Chi Minh City (VN); Shishir Kumar, Greater Noida (IN); Vinay Kumar, Greater Noida (IN)

(21) Appl. No.: 18/637,174

(22) Filed: Apr. 16, 2024

(51) Int. Cl. G11C 11/16

(52) U.S. Cl. CPC G11C 11/1675; G11C 11/1657; G11C 11/1659

(57) ABSTRACT

An example is a circuit. The circuit includes a memory array, a mimic column, a mimic resistor, and a calibration circuit. The mimic column is along a periphery of the memory array. The mimic resistor is in a path through the mimic column. The calibration circuit is configured to calibrate a voltage for writing a memory cell in the memory array. The calibration circuit is electrically connected to the mimic resistor. A voltage may be calibrated, such as by the calibration circuit, using the mimic column. A value may be written to a memory cell of the memory array using the calibrated voltage.

### TECHNICAL FIELD

The present disclosure relates to memory circuits, and more particularly, calibrating a voltage used to write a value to a memory cell.

### BACKGROUND

Magnetoresistive random access memory (MRAM) is a type of random access memory (RAM) that stores data using magnetization. An MRAM cell typically includes a magnetic storage element that is capable of holding a magnetization indicative of data stored by the MRAM cell. MRAM may be more dense than other memory technologies. Other characteristics of MRAM may make MRAM preferable over other memory technologies, such as dynamic RAM (DRAM) and static RAM (SRAM).

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a block diagram of a memory block including a write driver for write calibration according to some examples.

FIG. 2 depicts a magnetoresistive random access memory (MRAM) cell according to some examples.

FIG. 3 depicts a mimic cell according to some examples.

FIGS. 4A and 4B are a circuit diagram of a portion of the memory block of FIG. 1 according to some examples.

FIG. 5 is a flowchart of a method for performing a write operation on a memory cell according to some examples.

FIG. 6 is a block diagram of a memory block including a word line driver for write calibration according to some examples.

FIGS. 7A and 7B are a circuit diagram of a portion of the memory block of FIG. 6 according to some examples.

FIG. 8 is a flowchart of a method for performing a write operation on a memory cell according to some examples.

FIG. 9 depicts a diagram of an example computer system on which some examples of the present disclosure may operate.

### DETAILED DESCRIPTION

Aspects of the present disclosure relate to voltage calibration for a write operation. Some MRAM technologies implement a magnetic tunnel junction (MTJ) as the memory element. For some MTJs, large write currents, such as up to approximately 0.4 mA, may be needed to write a value to the corresponding MTJ. However, resistances along an electrical path through which the write current flows to write the MTJ may be too large to permit such a large write current to flow through the MTJ. In many instances, no or insufficient headroom is available in a power supply voltage to generate a sufficient write current.

Various implementations have attempted to supply a sufficient write voltage; however, such implementations have disadvantages. Some implementations require large transistor size in a circuit that provides the write voltage. Some implementations require a circuit to be on even during standby operation, which may consume unnecessary current and power. Still other implementations may have a stability challenge based on resistances of MTJs, which may change for a large range during writing.

Examples described herein provide a calibration circuit for calibrating a voltage for writing a memory cell, such as an MRAM cell including an MTJ, of a memory array. In some examples, the calibration circuit may calibrate a voltage to be selectively applied to a source line or a bit line electrically connected to the memory cell to be written. In some examples, the calibration circuit may calibrate a voltage to be applied to a word line electrically connected to the memory cell to be written. A mimic column is implemented along a periphery of the memory array, which emulates or replicates columns and corresponding source and bit lines of the memory array. The mimic column includes mimic cells that emulate or replicate the memory cells, except that the mimic cells are short circuited across and/or do not include a memory element, e.g., an MTJ. A mimic resistor is in the source line or bit line, and the mimic resistor is equal to an average resistance of the resistances of the memory elements of the memory cells. Hence, a path to a given memory cell may be emulated or replicated by a path to a mimic cell in a same row as the given memory cell, where the resistance of the mimic resistor emulates or replicates the resistance of the memory element to be written. The calibration circuit detects a voltage drop across the mimic resistor in a calibration phase and responsively calibrates the voltage for writing the memory cell such that sufficient current flows through the memory element during a write operation. After the calibration phase, a write operation is performed using the calibrated voltage.

Technical advantages of the present disclosure include, but are not limited to, providing sufficient write current to write memory elements. Further, voltage drops caused by parasitic resistances may be excluded to determine whether a sufficient voltage or current is through a memory element. In some examples, no or little current or power is consumed in standby modes. In some examples, no or little headroom is needed for a power supply voltage. In some examples, a small area may be used by the calibration circuit. Various examples may be process, voltage, and temperature independent. Other and/or additional advantages and benefits may be achieved in various examples.

Various modification may be made to examples described herein. Examples described herein may be described in the context of implementing various logic. Logic circuits may be modified and may implement equivalent logic circuits. Inverse logic levels may be implemented instead of and/or in addition to logic levels described herein. Examples described herein are described in the context of rows and columns. Rows and columns are used herein in the context of arrays merely to indicate relative orientation between a row and a column. In some examples, a column described herein may be considered a row, and a row described herein may be considered a column. Any methodology described herein may be performed in any logical order. Such modifications may implement a same or similar functionality and may achieve advantages and benefits described above.

A node of a circuit may be described with a reference name. The node may carry a signal and/or have a voltage thereon. The signal and/or voltage on the node may follow a same reference name. The presence of a node indicates the presence of a corresponding signal and/or voltage similarly named, and the presence of a signal and/or voltage indicates the presence of a corresponding node similarly named on which is that signal and/or voltage. For example, a comparator output node (COMP_OUT) has a comparator output signal (COMP_OUT).

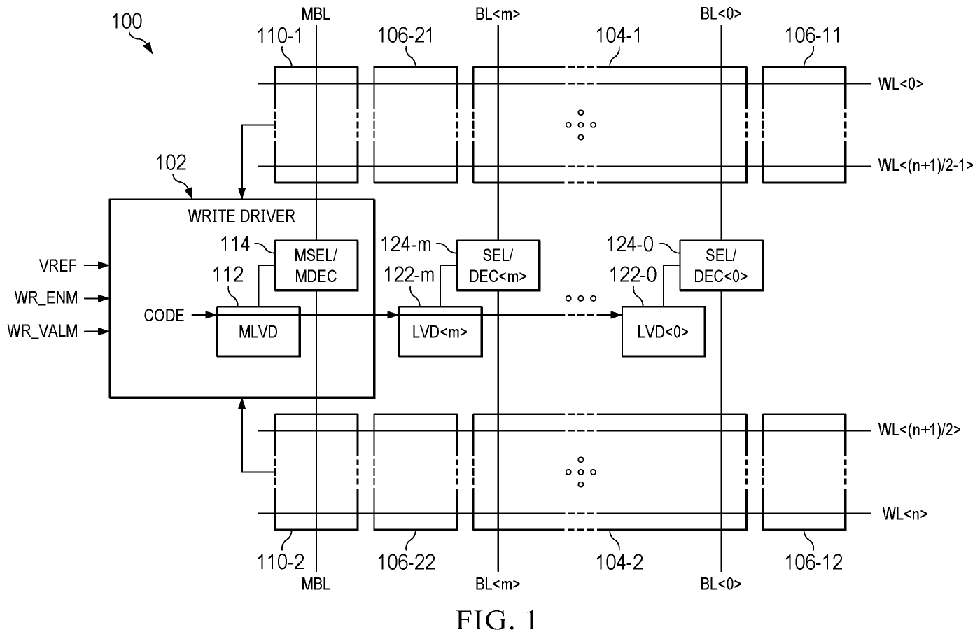

FIG. 1 is a block diagram of a memory block 100 including a write driver 102 for write calibration according to some examples. The memory block 100 includes a memory array of memory cells. The memory array (hereinafter, memory array 104) includes a first portion 104-1 and a second portion 104-2. The first portion 104-1 may include, for example, half of the memory cells of the memory array 104, and the second portion 104-2 may include, for example, another half of the memory cells of the memory array 104. The memory array 104 includes (n+1) rows and (m+1) columns of memory cells. As detailed subsequently, a memory cell may be a magnetoresistive random access memory (MRAM) cell, and the MRAM cell may be a magnetic tunnel junction (MTJ) MRAM cell.

Word lines (WLs) traverse respective rows in the memory array 104, and hence, with (n+1) rows, WL<0:n> traverse respective rows. Source lines (SLs) (not shown) and bit lines (BLs) traverse respective columns in the memory array 104, and hence, with (m+1) columns, SL<0:m> (not shown) and BL<0:m> traverse respective columns. As detailed subsequently, a memory cell at row i and column j in the memory array 104 is electrically connected to WL<i>, SL<j>, and BL<j>. In the illustrated example, WL<0:(n+1)/2-1> and respective memory cells are across or in the first portion 104-1 of the memory array 104, and WL<(n+1)/2:n> and respective memory cells are across or in the second portion 104-2 of the memory array 104.

Dummy columns including first column portions 106-11, 106-21 and second column portions 106-12, 106-22 are along respective periphery columns of memory cells of the memory array 104 and are outside of the memory array 104. A first dummy column (hereinafter, dummy column 106-1) includes the first column portion 106-11 and the second column portion 106-12, and a second dummy column (hereinafter, dummy column 106-2) includes the first column portion 106-21 and the second column portion 106-22. The dummy column 106-1 is along a column of memory cells electrically connected to BL<0> in the memory array 104. The dummy column 106-2 is along a column of memory cells electrically connected to BL<m> in the memory array 104. Each dummy column 106-1, 106-2 may include dummy cells that are a same type of cell as the memory cells of the memory array 104. The dummy cells may align with respective rows of memory cells in the memory array 104. The dummy cells may, for example, not be electrically coupled to another device. The dummy cells may permit improved or more consistent performance of the memory cells in the memory array 104 by providing a similar or same neighboring environment in which the memory cells along a periphery of the memory array operate.

A mimic column (hereinafter, mimic column 110) having a first column portion 110-1 and a second column portion 110-2 is along the dummy column 106-2, and/or in some examples, are along periphery columns of memory cells of the memory array 104 and are outside of the memory array 104. The mimic column 110 includes (n+1) number of mimic cells. The mimic cells align with respective rows of memory cells in the memory array 104. As detailed subsequently, a mimic cell is generally physically the same type of cell as the memory cell except with the memory element (e.g., MTJ) of the memory cell short-circuited. The memory element may be omitted from the mimic cells.

A mimic source line (MSL) (not shown) and a mimic bit line (MBL) traverse the mimic column 110. The WLs that traverse respective rows in the memory array 104 further traverse the mimic column 110. As detailed subsequently, a mimic cell at row i in the mimic column 110 is electrically connected to WL<i>, the MSL, and the MBL.

The mimic column 110 with the MSL and MBL generally replicate a column of memory cells in the memory array 104 except without the memory elements. More specifically, the first column portion 110-1 of the mimic column 110 replicates a column of memory cells (without the memory elements) corresponding to WL<0:(n+1)/2-1> in the first portion 104-1, and the second column portion 110-2 of the mimic column 110 replicates a column of memory cells (without the memory elements) corresponding to WL<(n+1)/2:n> in the second portion 104-2. Generally, the mimic column 110 with the MSL and MBL may model parasitic impedances (e.g., resistances, such as metal line resistances) that may be implemented to calibrate, in the illustrated example, a write voltage on a SL and/or BL.

The write driver 102 is electrically coupled to the mimic column 110 to receive a voltage that is representative of a voltage across a memory element for writing the memory element. The write driver 102 includes circuitry that is configured to calibrate a write voltage provided on an SL or BL based on the voltage that is received from the mimic column 110.

The write driver 102 includes a mimic line voltage driver (MLVD) 112 and a mimic selection circuit and mimic column decoder (MSEL/MDEC) 114. The write driver 102 generates a codeword (CODE) based on the voltage received from the mimic column 110, and the MLVD 112 receives the CODE to generate a write voltage that is supplied to the MBL or MSL. The MSEL/MDEC 114 selectively electrically couples the voltage generated by the MLVD 112 or a voltage on a negative supply voltage node (VSS) to the MSL and selectively electrically couples the voltage generated by the MLVD 112 or the voltage on the VSS to the MBL.

Each column of the memory array has a respective line voltage driver (LVD) 122-0, . . . , 122-m (individually or collectively, LVD(s) 122) and a selection circuit and column decoder (SEL/DEC) 124-0, . . . , 124-m (individually or collectively, SEL/DEC(s) 124). The respective LVD 122 receives the CODE to generate a write voltage that is supplied to the respective BL or SL. The SEL/DEC 124 selectively electrically couples the voltage generated by the LVD 122 or the voltage on the VSS to the respective SL and selectively electrically couples the voltage generated by the LVD 122 or the voltage on the VSS to the respective BL.

As illustrated, the MLVD 112 and MSEL/MDEC 114 are, along a longitudinal direction of the mimic column 110, between the column portions 110-1, 110-2 of the mimic column 110, and the LVDs 122-0, . . . , 122-m and SEL/DEC 124-0, . . . , 124-m are, along respective longitudinal directions of columns of the memory cells of the memory array 104, between the portions of the respective columns of memory cells in the first portion 104-1 and second portion 104-2. The LVDs 122-0, . . . , 122-m and SEL/DEC 124-0, . . . , 124-m are between the first portion 104-1 and second portion 104-2. In the illustrated example, the LVDs 122-0, . . . , 122-m and SEL/DEC 124-0, . . . , 124-m bifurcate the memory array 104 (e.g., by being between the portions 104-1, 104-2), which reduces a longest distance a memory cell in a column is from its LVD 122. Reducing this longest distance may reduce a parasitic impedance (e.g., resistance) due to physical length of metal lines from the LVD 122 to the memory cell. In other examples, the MLVD 112, MSEL/MDEC 114, and LVDs 122-0, . . . , 122-m, and SEL/DEC 124-0, . . . , 124-m may physically divide a mimic column and memory array in different portions or may not physically divide a mimic column and memory array.

The write driver 102 has a mimic write enable node (WR_ENM), a mimic write value node (WR_VALM), and a reference voltage node (VREF). Signals and/or voltages on the WR_ENM, the WR_VALM, and the VREF may be supplied from a circuit external to the write driver 102, such as a memory controller, a processor, or the like.

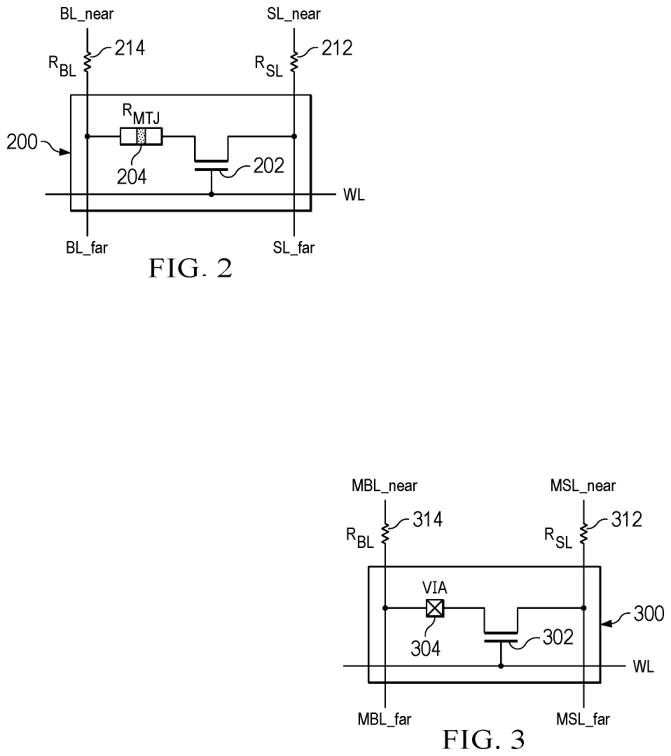

FIG. 2 depicts an MRAM cell 200 according to some examples. The MRAM cell 200 includes an access transistor 202 and an MTJ 204. A first source/drain node of the access transistor 202 is or is electrically connected to a SL node of the MRAM cell 200. A second source/drain node of the access transistor 202 is electrically connected to a first terminal of the MTJ 204. A second terminal of the MTJ 204 is or is electrically connected to a BL node of the MRAM cell 200. A gate node of the access transistor 202 is or is electrically connected to a WL node of the MRAM cell 200.

Within a memory array, the SL node of the MRAM cell 200 is electrically connected to a SL of the column in which the MRAM cell 200 is disposed. The SL includes a parasitic resistance (RSL) 212 between the MRAM cell 200 and the corresponding LVD 122 and/or SEL/DEC 124, which may be between the MRAM cell 200 and a neighboring MRAM cell more physically proximate to the LVD 122 and/or SEL/DEC 124. FIG. 2 indicates relative physical proximity to the corresponding LVD 122 and/or SEL/DEC 124 by the appendices “near” for closer physical proximity and “far” for further physical proximity. Within the memory array, the BL node of the MRAM cell 200 is electrically connected to a BL of the column in which the MRAM cell 200 is disposed. The BL includes a parasitic resistance (RBL) 214 between the MRAM cell 200 and the corresponding LVD 122 and/or SEL/DEC 124, which may be between the MRAM cell 200 and a neighboring MRAM cell more physically proximate to the LVD 122 and/or SEL/DEC 124. Within the memory array, the WL node of the MRAM cell 200 is electrically connected to a WL of the row in which the MRAM cell 200 is disposed.

FIG. 3 depicts a mimic cell 300 according to some examples. The mimic cell 300 includes an access transistor 302 and a shorting element, which is illustrated as a metal via 304. A first source/drain node of the access transistor 302 is or is electrically connected to a SL node of the mimic cell 300. A second source/drain node of the access transistor 302 is electrically connected a BL node of the mimic cell 300 (e.g., short-circuited to the BL node through the shorting element). A gate node of the access transistor 302 is or is electrically connected to a WL node of the mimic cell 300.

Within a mimic column, the SL node of the mimic cell 300 is electrically connected to the MSL. The MSL includes a parasitic resistance (RSL) 312 between the mimic cell 300 and the MLVD 112 and/or MSEL/MDEC 114, which may be between the mimic cell 300 and a neighboring mimic cell more physically proximate to the MLVD 112 and/or MSEL/MDEC 114. FIG. 3 indicates relative physical proximity to the corresponding MLVD 112 and/or MSEL/MDEC 114 by the appendices “near” for closer physical proximity and “far” for further physical proximity. Within the mimic column, the BL node of the mimic cell 300 is electrically connected to the MBL. The MBL includes a parasitic resistance (RBL) 314 between the mimic cell 300 and the corresponding MLVD 112 and/or MSEL/MDEC 114, which may be between the mimic cell 300 and a neighboring mimic cell more physically proximate to the MLVD 112 and/or MSEL/MDEC 114. The WL node of the mimic cell 300 is electrically connected to a WL of the row in which the mimic cell 300 is disposed.

As described in more detail subsequently, a mimic column 110 of mimic cells closely replicates or approximates the parasitic impedances (e.g., resistances) and drain-to-source resistances of access transistors of columns of the memory array 104. This allows a resistor to be implemented in, e.g., the MBL (or MSL) that approximates the resistance of the MTJs of the memory cells of the memory array 104. A voltage across the resistor may be detected to determine approximately a voltage across an MTJ to be written. This allows the write driver 102 to calibrate the voltage across the MTJ such that a sufficient current through the MTJ may be supplied for writing.

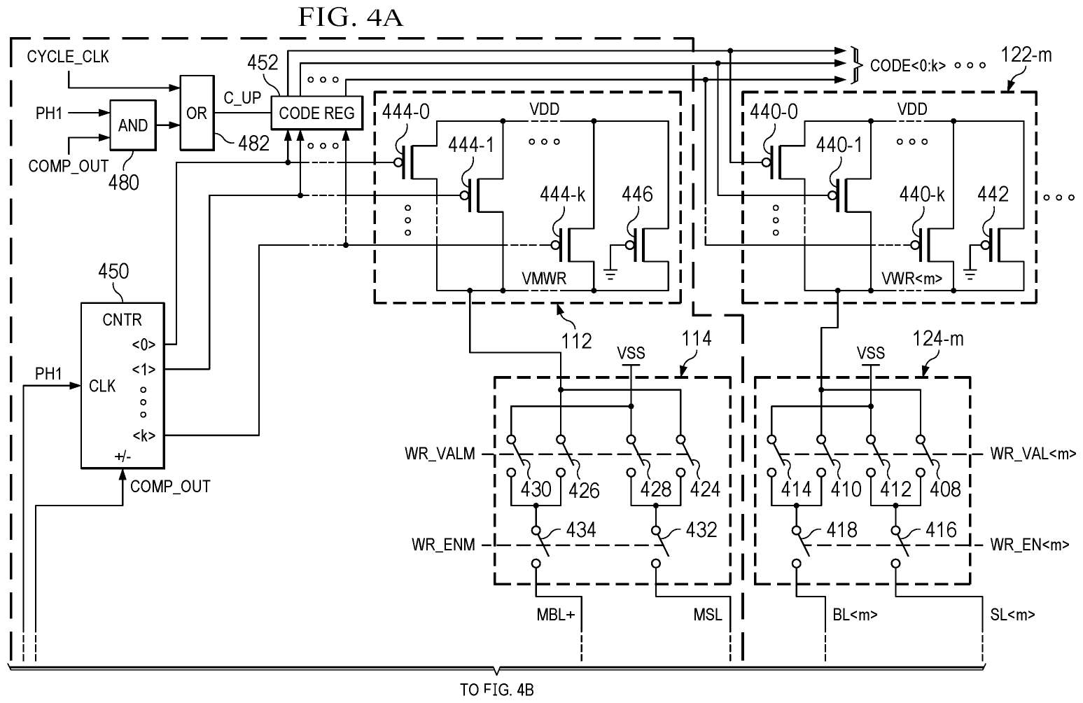

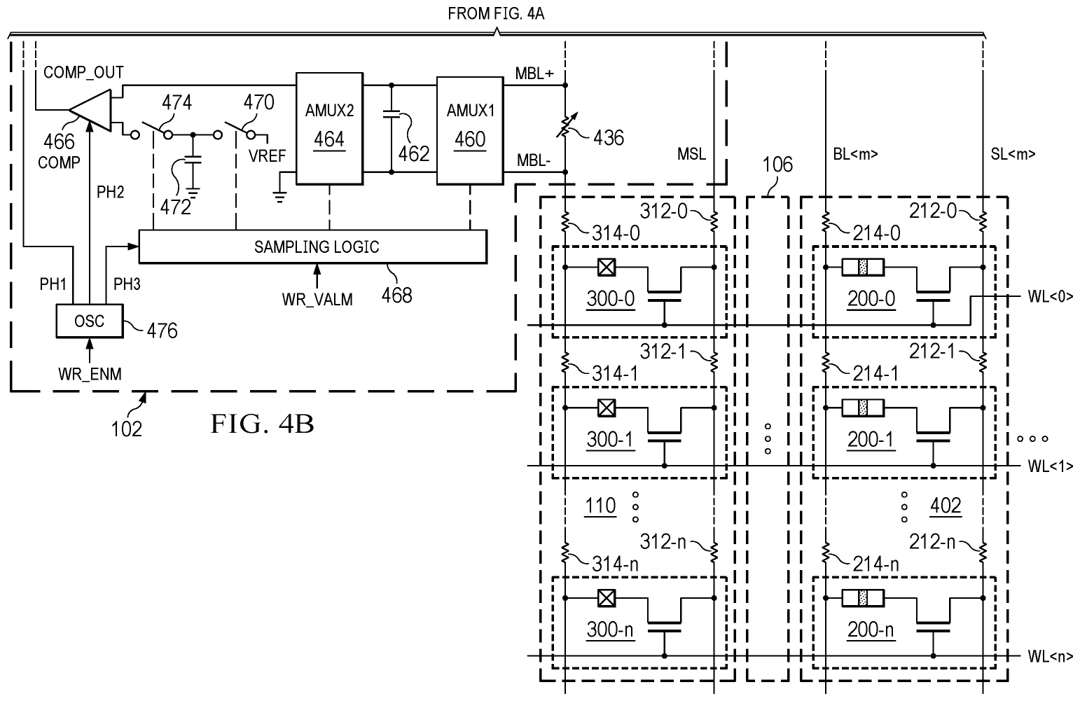

FIGS. 4A and 4B are a circuit diagram of a portion of the memory block 100 of FIG. 1 according to some examples. A memory column 402 is shown as a portion of the memory array 104. The remainder of the memory array 104 and other corresponding circuits are understood from the illustrated portion. The memory column 402 is a periphery column of the memory array 104 and corresponds with BL<m> and SL<m>. A dummy column 106 and a mimic column 110 are along the memory column 402, with the dummy column 106 between the memory column 402 and the mimic column 110.

The memory column 402 includes (n+1) number of MRAM cells 200 (where each memory cell is appended with a number indicating in which row the MRAM cell 200 is disposed). Corresponding parasitic resistances (RSL) 212 in the SL<m> and parasitic resistances (RBL) 214 in the BL<m> are also in the memory column 402. The parasitic resistances 212, 214 result from metal routing in the respective SL<m> and BL<m> in the memory column 402.

The mimic column 110 includes (n+1) number of mimic cells 300 (where each mimic cell is appended with a number indicating in which row the mimic cell 300 is disposed). Corresponding parasitic resistances (RSL) 312 in the MSL and parasitic resistances (RBL) 314 in the MBL are also in the mimic column 110. The parasitic resistances 312, 314 result from metal routing in the respective MSL and MBL in the mimic column 110. A mimic cell 300 and an MRAM cell 200 in a same row are electrically connected to a same WL (e.g., mimic cell 300-n and MRAM cell 200-n are electrically connected to WL<n>).

The SEL/DEC<m> 124-m is electrically connected to the SL<m> and BL<m>, and the LVD<m> 122-m is electrically connected to the SEL/DEC<m> 124-m. The SEL/DEC<m> 124-m includes switches 408, 410, 412, 414, 416, 418. The SEL/DEC<m> 124-m is configured to selectively apply a voltage on a write voltage node (VWR<m>) of the LVD<m> 122-m or the voltage of the VSS to the SL<m> and to selectively apply the voltage on the VWR<m> of the LVD<m> 122-m or the voltage of the VSS to the BL<m>. Respective first terminals of the switches 408, 410 are electrically connected to the VWR<m>, and respective first terminals of the switches 412, 414 are electrically connected to the VSS. Respective second terminals of the switches 408, 412 are electrically connected to a first terminal of the switch 416, and a second terminal of the switch 416 is electrically connected to the SL<m>. Respective second terminals of the switches 410, 414 are electrically connected to a first terminal of the switch 418, and a second terminal of the switch 418 is electrically connected to the BL<m>. The switches 408-414 are controlled by a signal on a column write value node (WR_VAL<m>), and the switches 416, 418 are controlled by a signal on an column write enable node (WR_EN<m>). The signals on the WR_VAL<m> and the WR_EN<m> control the switches 408-418 to be selectively opened or closed. The switches 408-418 may be or include a transistor, a transmission gate, or another switch. The switches 408-418 may implement one or more analog multiplexers.

When the SEL/DEC<m> 124-m selectively electrically connects the VWR<m> to one of the SL<m> or the BL<m>, the SEL/DEC<m> 124-m selectively electrically connects the VSS to the other of the SL<m> or the BL<m>. The signal on the WR_EN<m> controls whether writing of an MRAM cell 200 in the memory column 402 is enabled. If not enabled, the signal on the WR_EN<m> causes both switches 416, 418 to be in an opened state, which de-couples the voltages on the VWR<m> and VSS from the SL<m> and the BL<m>. If enabled, the signal on the WR_EN<m> causes both switches 416, 418 to be in a closed state, which may electrically connect the VWR<m> to the SL<m> and the VSS to the BL<m> or vice versa depending on the states of the switches 408-414. The signal on the WR_VAL<m> controls which voltage is to be applied to the SL<m> and BL<m>, and hence, whether a logical “0” or “1” is to be written to an MRAM cell 200. When one of the switches 408, 412 is in a closed state, the other is in an open state, and both switches 408, 412 may be in an open state simultaneously. When one of the switches 410, 414 is in a closed state, the other is in an open state, and both switches 410, 414 may be in an open state simultaneously. When one of the switches 408, 410 is in a closed state, the other is in an open state, and both switches 408, 410 may be in an open state simultaneously. When one of the switches 412, 414 is in a closed state, the other is in an open state, and both switches 412, 414 may be in an open state simultaneously. Generally, the switches 408, 414 may be in closed states simultaneously, which may electrically connect the VWR<m> to the SL<m> and the VSS to the BL<m> for writing a logical “1”. Generally, the switches 410, 412 may be in closed states simultaneously, which may electrically connect the VWR<m> to the BL<m> and the VSS to the SL<m> for writing a logical “0”.

The MSEL/MDEC 114 is electrically connected to the MSL and a first terminal of the MBL (MBL+), and the MLVD 112 is electrically connected to the MSEL/MDEC 114. The MSEL/MDEC 114 includes switches 424, 426, 428, 430, 432, 434. The MSEL/MDEC 114 is configured to selectively apply a voltage on a mimic write voltage node (VMWR) of the MLVD 112 or the voltage of the VSS to the MSL and to selectively apply the voltage on the VMWR of the MLVD 112 or the voltage of the VSS to the MBL+. Respective first terminals of the switches 424, 426 are electrically connected to the VMWR, and respective first terminals of the switches 428, 430 are electrically connected to the VSS. Respective second terminals of the switches 424, 428 are electrically connected to a first terminal of the switch 432, and a second terminal of the switch 432 is electrically connected to the MSL. Respective second terminals of the switches 426, 430 are electrically connected to a first terminal of the switch 434, and a second terminal of the switch 434 is electrically connected to the MBL+. The switches 424-430 are controlled by a signal on the WR_VALM, and the switches 432, 434 are controlled by a signal on the WR_ENM. The signals on the WR_VALM and the WR_ENM control the switches 424-434 to be selectively opened or closed. The switches 424-434 may be or include a transistor, a transmission gate, or another switch. The switches 424-434 may implement one or more analog multiplexers.

When the MSEL/MDEC 114 selectively electrically connects the VMWR to one of the MSL or the MBL+, the MSEL/MDEC 114 selectively electrically connects the VSS to the other of the MSL or the MBL+. The signal on the WR_ENM controls whether write calibration using the mimic column 110 is enabled. If not enabled, the signal on the WR_ENM causes both switches 432, 434 to be in an opened state, which de-couples the voltages on the VMWR and VSS from the MSL and the MBL+. If enabled, the signal on the WR_ENM causes both switches 432, 434 to be in a closed state, which may electrically connect the VMWR to the MSL and the VSS to the MBL+ or vice versa depending on the states of the switches 424-430. The signal on the WR_VALM controls which voltage is to be applied to the MSL and MBL+. When one of the switches 424, 428 is in a closed state, the other is in an open state, and both switches 424, 428 may be in an open state simultaneously. When one of the switches 426, 430 is in a closed state, the other is in an open state, and both switches 426, 430 may be in an open state simultaneously. When one of the switches 424, 426 is in a closed state, the other is in an open state, and both switches 424, 426 may be in an open state simultaneously. When one of the switches 428, 430 is in a closed state, the other is in an open state, and both switches 428, 430 may be in an open state simultaneously. Generally, the switches 424, 430 may be in closed states simultaneously, which may electrically connect the VMWR to the MSL and the VSS to the MBL+. Generally, the switches 426, 428 may be in closed states simultaneously, which may electrically connect the VMWR to the MBL+ and the VSS to the MSL.

A mimic resistor 436 is electrically connected between the MBL+ and a second terminal of the MBL (MBL−). The MBL-extends as the MBL in the mimic column 110. Hence, the mimic resistor 436 is in the MBL. In other examples, the mimic resistor 436 may be in the MSL. The resistance of the mimic resistor 436 approximates the average resistance of the resistances of the MTJs 204 of the MRAM cells 200 of the memory array 104. The mimic resistor 436 may be or include a polysilicon resistor and may be trimmable or may be programmable after manufacturing to implement a target resistance for the mimic resistor 436. After manufacturing, the resistances of the MTJs 204 may be measured, which may accommodate for process variation of the MTJs 204, and based on the measured resistances, the average resistance of the measured resistances, to which the mimic resistor 436 is to be trimmed or programmed, may be determined.

The LVD<m> 122-m includes (k+1) number of transistors 440-0, 440-1, . . . 440-k (individually or collectively, transistor(s) 440) and a transistor 442. In the illustrated example, the transistors 440, 442 are p-type transistors (e.g., p-type field effect transistors (pFETs)). Each of the transistors 440, 442 has a source node electrically connected to a positive supply voltage node (VDD) and has a drain node electrically connected to the VWR<m>. Gate nodes of the transistors 440 are electrically connected to respective codeword bit nodes (CODE<0:k>). A gate node of the transistor 442 is electrically connected to a ground node. In some examples, respective ratios of channel width to channel length (W/L) vary among the transistors 440. For example, a W/L ratio of the transistor 440-1 may be twice a W/L ratio of the transistor 440-0; a W/L ratio of the transistor 440-2 may be four times a W/L ratio of the transistor 440-0; and a W/L ratio of the transistor 440-k may be 2 k a W/L ratio of the transistor 440-0. In other examples, different W/L ratios may be implemented. In still other examples, the W/L ratios of the transistors 440 may be equal. The transistor 442 may be a weak transistor that provides a high resistance path between the VDD and the VWR<m>.

The MLVD 112 includes (k+1) number of transistors 444-0, 444-1, . . . 444-k (individually or collectively, transistor(s) 444) and a transistor 446. In the illustrated example, the transistors 444, 446 are p-type transistors (e.g., pFETs). Each of the transistors 444, 446 has a source node electrically connected to the VDD and has a drain node electrically connected to the VMWR. Gate nodes of the transistors 444 are electrically connected to respective counter output nodes (<0:k>) of a counter 450. A codeword register 452 includes (k+1) number of latches. Each latch of the codeword register 452 has an input node that is electrically connected to a respective counter output node (<0:k>) of the counter 450 and has an output node that is a respective codeword bid node (CODE<0:k>). A gate node of the transistor 446 is electrically connected to a ground node. The MLVD 112 replicates the LVDs of the memory columns in the memory array 104. The transistor 444 that has a gate node electrically connected to a given counter output node has an equal W/L ratio as the transistor that has a gate node electrically connected to the corresponding codeword bit node. The W/L ratio of the transistor 444-0 (which has a gate node connected to counter output node <0>) is equal to the W/L ratio of the transistor 440-0 (which has a gate node connected to CODE<0>); the W/L ratio of the transistor 444-1 (which has a gate node connected to counter output node <1>) is equal to the W/L ratio of the transistor 440-1 (which has a gate node connected to CODE<1>); etc. The transistor 446 may be a weak transistor that provides a high resistance path between the VDD and the VMWR.

Generally, the mimic column 110, MSEL/MDEC 114, and MLVD 112 replicate the electrical paths from the VDD to the VSS in the memory columns, SEL/DECs 124, and LVDs 122 in the memory array 104. For example, assuming the same signals are on the counter output nodes <0:k> and CODE<0:k> and a memory cell at row <i> in column <m> is to be written, the voltages on VMWR and VWR<m> are substantially equal; the sum of parasitic resistances of the electrical path through the memory cell and the sum of parasitic resistances of the electrical path through a corresponding mimic cell are substantially equal; and the source-to-drain resistances of the access transistors in the memory cell and corresponding mimic cell are substantially equal. As stated previously, the resistance of the mimic resistor 436 approximates the average resistance of the resistances of the MTJs 204 of the MRAM cells 200 of the memory array 104. This may be generally expressed as the following:

$${V}_{VMWR} - {V}_{V S S} = {V}_{V W R < m >} - {V}_{V S S} \\ {\sum }_{x = 0}^{i} {R}_{MSL , x} + {R}_{MBL , x} = {\sum }_{x = 0}^{i} {R}_{S L < m > , x} + {R}_{B L < m > , x} \\ {R}_{MDS , i} = {R}_{D S < m > , i} \\ {R}_{M M T J} = {\hat{R}}_{M T J} \approx {R}_{M T J < m > , i}$$

Where V_{VMWR} and V_{VWR<m>} are voltages on the VMWR and VWR<m>, respectively; V_{VSS} is the voltage on the VSS; R_{MSL,x} and R_{MBL,x} are the parasitic resistances in the MSL and MBL for mimic cell in row x, respectively; R_{SL<m>,x} and R_{BL<m>,x} are the parasitic resistances in the SL<m> and BL<m> for a memory cell in row x, respectively; R_{MDS,i} and R_{DS<m>,i} are drain-to-source resistances of access transistors in the mimic cell and the memory cell (in column m) in row i; R_{MMTJ} is the resistance of the mimic resistor 436; \hat{R}_{MTJ} is the average resistance of resistances of the MTJs of the memory array; and R_{MTJ<m>,i} is the resistance of the MTJ of the memory cell in column m in row i. Hence:

$${I}_{M , i} [ {R}_{MMTJ} + {R}_{MDS , i} + {\sum }_{x = 0}^{i} {R}_{MSL , x} + {R}_{MBL , x} ] = {I}_{< m > , i} [ {R}_{M T J < m > , i} + {R}_{D S < m > , i} + {\sum }_{x = 0}^{i} {R}_{SL , x} + {R}_{BL , x} ]$$

Where I_{M,i} is the current through the mimic cell at row i, and I_{<m>,i} is the current through the memory cell in column m in row i. Given the expressions above, I_{M,i}≈I_{<m>,i}, and the above equation may simplified to the following expression:

$${I}_{M , i} {R}_{M M T J} \approx {I}_{< m > , i} {R}_{M T J < m > , i}$$

The voltage drop across the mimic resistor 436 may therefore approximate the voltage drop across the MTJ 204 of the MRAM cell 200 and, further, the current through the MTJ 204 of the MRAM cell 200.

Respective input nodes of a first analog multiplexer (AMUX1) 460 are electrically connected to the MBL+ and MBL−, and hence, a voltage drop across the mimic resistor 436 is input to the AMUX1 460. The AMUX1 460 has output nodes electrically connected to respective terminals of a capacitor 462. Respective input nodes of a second analog multiplexer (AMUX2) 464 are electrically connected to the terminals of the capacitor 462. A first output node of the AMUX2 464 is electrically connected to the first input node of a comparator 466, and a second output node of the AMUX2 464 is electrically connected to a ground node.

The VREF is electrically connected to a first terminal of a switch 470. A second terminal of the switch 470 is electrically connected to a first terminal of a capacitor 472, which is further electrically connected to a first terminal of a switch 474. A second terminal of the capacitor 472 is electrically connected to the ground node. A second terminal of the switch 474 is electrically connected to a second input terminal of the comparator 466. An output node (COMP_OUT) of the comparator 466 is electrically connected to an increase/decrease input node of the counter 450.

The AMUX1 460, AMUX2 464 and switches 470, 474 are controlled by sampling logic 468. The AMUX1 460, as controlled by the sampling logic 468, is configured to be selectively closed to pass the voltage drop across the mimic resistor 436 to the capacitor 462 (and hence, charge the capacitor 462 to the voltage drop across the mimic resistor 436) or to be selectively opened. The AMUX2 464, as controlled by the sampling logic 468, is configured to be selectively open or closed in a first closed state or in a second closed state. In the first closed state, the first input node of the AMUX2 464 is electrically coupled to the first output node of the AMUX2 464, and the second input node of the AMUX2 464 is electrically coupled to the second output node of the AMUX2 464. This causes the voltage V_{MBL+}-V_{MBL-} charged on the capacitor 462 to be electrically coupled to the first input node of the comparator 466. In the second closed state, the second input node of the AMUX2 464 is electrically coupled to the first output node of the AMUX2 464, and the first input node of the AMUX2 464 is electrically coupled to the second output node of the AMUX2 464. This causes the voltage −(V_{MBL+}-V_{MBL-}) charged on the capacitor 462 to be electrically coupled to the first input node of the comparator 466. The AMUX2 464 may selectively switch the polarity of the voltage from the capacitor 462 that is input to the comparator 466. In an open state, the AMUX2 464 de-couples the voltage of the capacitor 462 from the comparator 466.

The sampling logic 468 controls the AMUX1 460 and AMUX2 464 based on signals on the WR_VALM and a clock signal on a third phase output node (PH3) of an oscillator 476. The sampling logic 468 controls the AMUX1 460 to be closed during a charging phase and open in a pass-through phase, which phases are determined based on the clock signal on the PH3. The sampling logic 468 also controls the AMUX2 464 to be open during the charging phase and closed in the first closed state or the second closed state during the pass-through phase. In the pass-through phase, the sampling logic 468 controls the AMUX2 464 to be closed in the first closed state or the second closed state based on the signal on the WR_VALM. If the signal on the WR_VALM indicates that a logical “0” is to be written, the sampling logic 468 may control the AMUX2 464 to be in the first closed state. If the signal on the WR_VALM indicates that a logical “1” is to be written, the sampling logic 468 may control the AMUX2 464 to be in the second closed state. Hence, during the charging phase, the capacitor 462 is charged to the voltage V_{MBL+}-V_{MBL-}, and during the pass-through phase, the voltage V_{MBL+}-V_{MBL-} or the voltage −(V_{MBL+}-V_{MBL-}) is applied to the first input node of the comparator 466.

The sampling logic 468 controls the switches 470, 474 based on the signal on the clock signal on the PH3. The sampling logic 468 controls the switch 470 to be closed and the switch 474 to be open during the charging phase, which is based on the clock signal on the PH3. The sampling logic 468 controls the switch 474 to be closed and the switch 470 to be open during the pass-through phase, which is based on the clock signal on the PH3. Hence, during the charging phase, the capacitor 472 is charged to the voltage of the VREF, and during the pass-through phase, the voltage of the VREF is applied to the second input node of the comparator 466.

The comparator 466 compares the voltages on the first and second input nodes of the comparator 466 when triggered by a clock signal on a second phase output node (PH2) of the oscillator 476 and outputs a logical “1” or “0” based on the comparison. When the voltage on the first input node (e.g., from the AMUX2 464) is greater than the voltage on the second input node (e.g., from the capacitor 472), the comparator 466 outputs a logical “1” when triggered, and when the voltage on the first input node (e.g., from the AMUX2 464) is less than the voltage on the second input node (e.g., from the capacitor 472), the comparator 466 outputs a logical “0” when triggered.

The output signal on the COMP_OUT from the comparator 466 is input on the increase/decrease input node of the counter 450. The counter 450 increases or decreases the codeword on the counter output nodes <0:k> based on the output signal on the COMP_OUT and when triggered by a clock signal on a first phase output node (PH1) of the oscillator 476. The counter 450 may implement a successive counting approach or another counting approach.

The oscillator 476 is configured to generate and output the clock signals on the PH1, PH2, PH3 when the signal on the WR_ENM indicates that write calibration is enabled. The clock signals are not generated and output on the PH1, PH2, PH3 when the signal on the WR_ENM indicates that write calibration is not enabled. The clock signals may have a same frequency and may be phase offset relative to each other. The phase offsets may permit appropriate set up time for sampling voltages at different components.

The COMP_OUT and PH1 are electrically connected to respective input nodes of an AND gate 480. An output node of the AND gate 480 is electrically connected to a first input node of an OR gate 482. A second input node of the OR gate 482 is electrically connected to a cycle last clock node (CYCLE_CLK). An output node of the OR gate 482 is a codeword update node (C_UP) and is electrically connected to trigger input nodes of the codeword register 452. When the clock signal is a logical “1” and COMP_OUT is a logical “1” (e.g., when the magnitude of the voltage drop across the mimic resistor 436 exceeds the voltage on the VREF), the signal on C_UP causes the codeword register 452 to sample and store the codeword on the counter output nodes <0:k> of the counter 450. A logical “1” on the CYCLE_CLK may also trigger the codeword register 452 to sample and store the codeword on the counter output nodes <0:k> of the counter 450, which may be a separate control for updating the codeword in the codeword register 452.

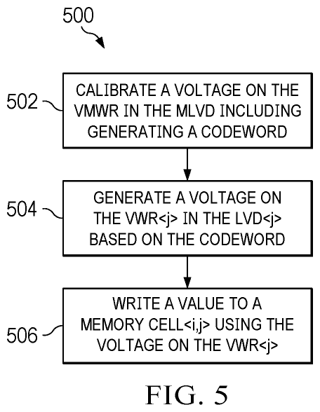

FIG. 5 is a flowchart of a method 500 for performing a write operation on a memory cell (e.g., MRAM cell 200) according to some examples. The method 500 is performed using the memory block 100 of FIGS. 1, 4A, and 4B. The method 500 may be performed for writing an MRAM cell 200 at row i and column j (designated MRAM cell 200-i,j), which is electrically connected to WL<i>, SL<j>, and BL<j>. The method 500 may be performed for simultaneously writing multiple memory cells in a same row that are to be written a same value. The method 500 may be performed iteratively for writing memory cells in a same row of the memory array with different values.

At block 502 of FIG. 5, a voltage on the VMWR in the MLVD 112 is calibrated, which includes generating a codeword. To enter calibration, the signal on the WR_ENM transitions from not enabled to enabled. The signals on the WR_EN<0:m> remain not enabled during the calibration. The signal on the WR_ENM being enabled causes the switches 432, 434 to be closed. The signal on the WR_VALM is set to be the same as the signal on the WR_VAL<j> when writing the MRAM cell 200-i,j. If the signal on the WR_VALM corresponds to writing a logical “1”, the switches 424, 430 are closed, and switches 426, 428 are open. This electrically connects the VMWR to the MSL and the VSS to the MBL. If the signal on the WR_VALM corresponds to writing a logical “0”, the switches 426, 428 are closed, and switches 424, 430 are open. This electrically connects the VSS to the MSL and the VMWR to the MBL. The signal on the WL<i> is asserted to turn on the access transistor 302 in the mimic cell 300-i, which causes a current path from the VMWR to the VSS. The current path is through the MSL and MBL (with corresponding parasitic resistances 312, 314), the access transistor 302 and shorting element (e.g., metal via 304) of the mimic cell 300-i, and the mimic resistor 436. The current path causes a voltage drop across the mimic resistor 436.

The signal on the WR_ENM being enabled causes the oscillator 476 to generate respective clock signals on the PH1, PH2, and PH3. The sampling logic 468 causes the AMUX1 460 to electrically connect the MBL+ and MBL− to the terminals of the capacitor 462 during a charging phase based on the clock signal on the PH3. The capacitor 462 is charged to the voltage drop across the mimic resistor 436 (e.g., V_{MBL+}-V_{MBL-}) During the charging phase, the sampling logic 468 causes the AMUX2 464 to de-couple the capacitor 462 from the comparator 466 and the ground node connected to the AMUX2 464. Further, during the charging phase, the sampling logic 468 causes the switch 474 to be open and the switch 470 to be closed, which charges the capacitor 472 to the voltage on the VREF and de-couples the capacitor 472 from the comparator 466. The capacitor 472 is charged to the voltage on the VREF (e.g., V_{VREF})

Then, in a pass-through phase based on the clock signal on the PH3, the sampling logic 468 causes the AMUX1 460 to be in an open state to de-couple the capacitor 462 from the mimic resistor 436, and the sampling logic 468 causes the AMUX2 464 to electrically connect the capacitor 462 to the first input node of the comparator 466. The sampling logic 468 causes the AMUX2 464 to be in a first or second closed state based on the signal on the WR_VALM. If the signal on the WR_VALM corresponds to writing a logical “0”, the sampling logic 468 causes the AMUX2 464 to be in a first closed state that applies +(V_{MBL+}-V_{MBL-}) to the first input of the comparator 466. If the signal on the WR_VALM corresponds to writing a logical “1”, the sampling logic 468 causes the AMUX2 464 to be in a second closed state that applies −(V_{MBL+}-V_{MBL-}) to the first input of the comparator 466. Further, in the pass-through phase, the sampling logic 468 causes the switch 470 to be open and the switch 474 to be closed, which electrically connects the capacitor 472 to the second input node of the comparator 466 and de-couples the capacitor 472 from the VREF.

During the pass-through phase, the comparator 466 compares the voltages on the input nodes of the comparator 466 when triggered by the clock signal on the PH2. The signal on the COMP_OUT is a logical “1” when the voltage on the first input node (electrically connected to the AMUX2 464) is greater than the voltage on the second input node (e.g., the capacitor 472). The signal on the COMP_OUT is a logical “0” when the voltage on the first input node (electrically connected to the AMUX2 464) is less than the voltage on the second input node (e.g., the capacitor 472). Due to the switching by the AMUX2 464 between the first closed state and the second closed state, more generally, the signal on the COMP_OUT is a logical “0” when the magnitude of the voltage drop across the mimic resistor 436 (as charged on the capacitor 462) is less than the voltage on VREF (as charged on the capacitor 472), and the signal on the COMP_OUT is a logical “1” when the magnitude of the voltage drop across the mimic resistor 436 (as charged on the capacitor 462) is greater than the voltage on VREF (as charged on the capacitor 472).

In the illustrated example, the counter 450 decreases the codeword on the counter output nodes (<0:k>) when triggered by the clock signal on the PH1 and the signal on the COMP_OUT is a logical “1” and increases the codeword on the counter output nodes (<0:k>) when triggered by the clock signal on the PH1 and the signal on the COMP_OUT is a logical “0.” Having each counter output node (<0:k>) be a logical “0” causes each of the transistors 444 in the MLVD 112 to be in an on state, which reduces the resistance between the VDD and the VMWR and causes the voltage on the VMWR to be closest to the voltage of the VDD. Conversely, having each counter output node (<0:k>) be a logical “1” causes each of the transistors 444 in the MLVD 112 to be in an off state, which increases the resistance between the VDD and the VMWR and causes the voltage on the VMWR to be furthest from and less than the voltage of the VDD. Combinations of logical “0”s and logical “1” vary the voltage on the VMWR between these endpoints. The transistor 446 is set in an on state by having its gate node being grounded, and the transistor 446 may be a weak transistor that has a high drain-to-source resistance to permit a voltage to be on the VMWR when each of the transistors 444 in the MLVD 112 is in an off state.

The changing of the codeword on the counter output nodes (<0:k>) therefore changes the voltage on the VMWR, which changes the current through the mimic cell 300-i and the voltage drop on the mimic resistor 436. The calibration process is therefore based on a feedback loop. The calibration process may continue until, for example, the codeword on the counter output nodes (<0:k>) converges to two values alternating in consecutive periods of the clock signal on the PH1. One of the values causes the magnitude of the voltage drop on the mimic resistor 436 to be greater than the voltage on the VREF, and the other value causes the magnitude of the voltage drop on the mimic resistor 436 to be less than the voltage on the VREF. Converging on these two values, such as in a successive approach, may result in the counter 450 generating a codeword that causes the voltage on the VMWR to be the lowest achievable voltage that permits the voltage drop on the mimic resistor 436 to be greater than the target write voltage (e.g., on the VREF).

The signal on WR_ENM may indicate that write calibration is not enabled when the calibration process concludes. The signal on WR_ENM indicating that write calibration is not enabled causes the oscillator 476 to stop generating clock signals on the PH1, PH2, and PH3, which disables the sampling logic 468, the comparator 466, and the counter 450. The signal on WR_ENM indicating that write calibration is not enabled also causes the switches 432, 434 to be in open states de-coupling the VMWR and VSS from the MSL and MBL.

The codeword register 452 latches the codeword on the counter output nodes (<0:k>) when triggered by the clock signal on the PH1 and the signal on the COMP_OUT is a logical “1” (e.g., when the counter 450 decreases the codeword). Hence, the codeword stored in the codeword register 452 is a value that causes the voltage drop on the mimic resistor 436 to be greater than the target write voltage (e.g., on the VREF). A signal on the CYCLE_CLK may be provided from externally from the memory block 100 to cause the codeword register 452 to latch another value.

Referring to block 504 of FIG. 5, a voltage on the VWR<j> in the LVD<j> is generated based on the codeword. The codeword that is latched by the codeword register 452 is provided on the CODE<0:k> to the LVD<j>. The LVD<j> operates to generate a voltage on the VWR<j> based on the value on the CODE<0:k> like the MLVD 112 operates to generate a voltage on the VMWR based on the value on the counter output nodes <0:k>. Due to the calibration process, the voltage on the VWR<j> should be sufficient to write the MRAM cell 200-i,j.

Referring to block 506 of FIG. 5, a value is written to the MRAM cell 200-i,j using the voltage on the VWR<j>. To write the MRAM cell 200-i,j, the signal on the WR_EN<j> transitions from not enabled to enabled. The signal on the WR_EN<j> being enabled causes the switches 416, 418 to be closed. The signal on the WR_VAL<j> is set for writing the MRAM cell 200-i,j. If the signal on the WR_VAL<j> corresponds to writing a logical “1”, the switches 408, 414 are closed, and switches 410, 412 are open. This electrically connects the VWR<j> to the SL<j> and the VSS to the BL<j>. If the signal on the WR_VAL<j> corresponds to writing a logical “0”, the switches 410, 412 are closed, and switches 408, 414 are open. This electrically connects the VSS to the SL<j> and the VWR<j> to the BL<j>. The signal on the WL<i> is asserted to turn on the access transistor 202 in the MRAM cell 200-i,j, which causes a current path from the VWR<j> to the VSS through the MRAM cell 200-i,j. The current path is through the SL<j> and BL<j> (with corresponding parasitic resistances 212, 214) and the access transistor 202 and memory element (e.g., MTJ 204) of the MRAM cell 200-i,j. The current path causes the memory element (e.g., MTJ 204) to be written.

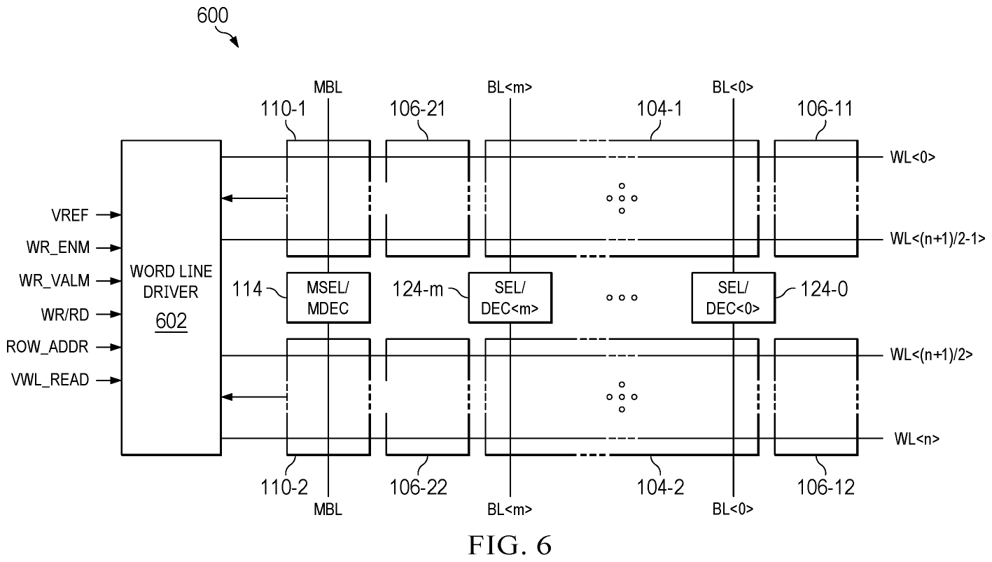

FIG. 6 is a block diagram of a memory block 600 including a word line driver 602 for write calibration according to some examples. The memory block 600 includes a memory array 104 of memory cells. The memory array 104 includes a first portion 104-1 and a second portion 104-2. Dummy columns 106-1, 106-2 (including column portions 106-11, 106-12, 106-21, 106-22) are along respective periphery columns of memory cells of the memory array 104 and are outside of the memory array 104. A mimic column 110 (including column portions 110-1, 110-2) are along the dummy column 106-2, and/or in some examples, are along periphery columns of memory cells of the memory array 104 and are outside of the memory array 104. The memory array 104 (including the portions 104-1, 104-2), dummy columns 106-1, 106-2, and mimic column 110 are like described above.

The word line driver 602 is electrically coupled to the mimic column 110 to receive a voltage that is representative of a voltage across a memory element for writing the memory element. The write driver 102 includes circuitry that is configured to calibrate a word line voltage provided on the WL based on the voltage that is received from the mimic column 110.

A MSEL/MDEC 114 selectively electrically couples the VDD or the VSS to the MSL and selectively electrically couples the VDD or the VSS to the MBL. Each column of the memory array has a respective SEL/DEC 124-0, . . . 124-m. The SEL/DEC 124 selectively electrically couples the VDD or the VSS to the respective SL and selectively electrically couples the VDD or the VSS to the respective BL.

The word line driver 602 has a WR_ENM, a WR_VALM, a VREF, a write/read selection node (WR/RD), row address nodes (ROW_ADDR), and a WL read voltage node (VWL_READ). Signals and/or voltages on the WR_ENM, the WR_VALM, the VREF, the WR/RD, the ROW_ADDR, and the VWL_READ may be supplied from a circuit external to the word line driver 602, such as a memory controller, a processor, or the like.

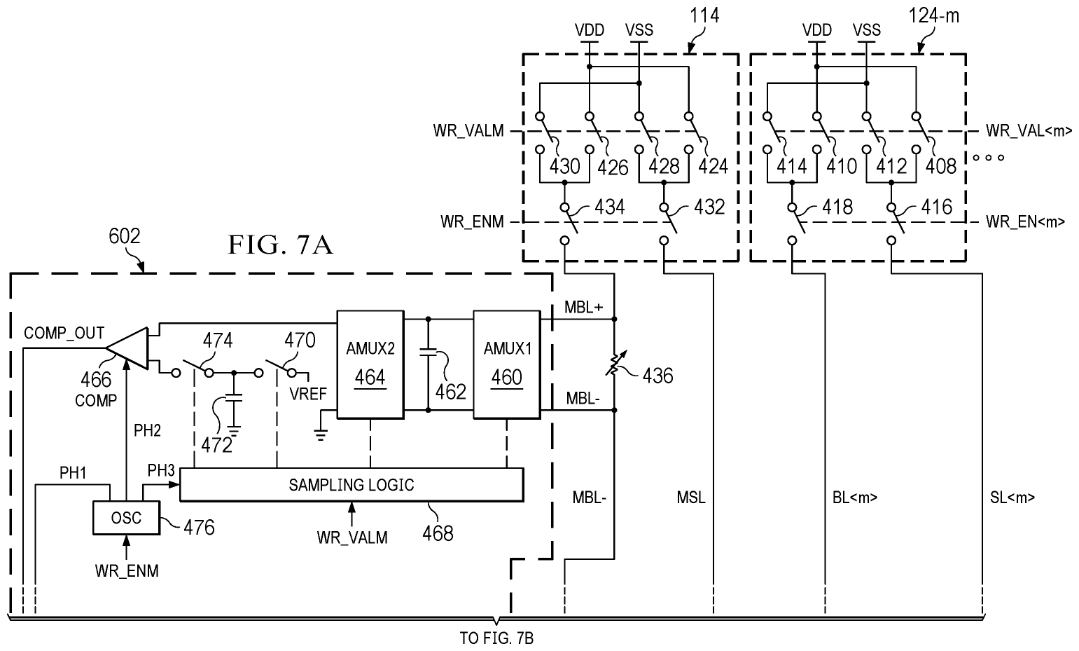

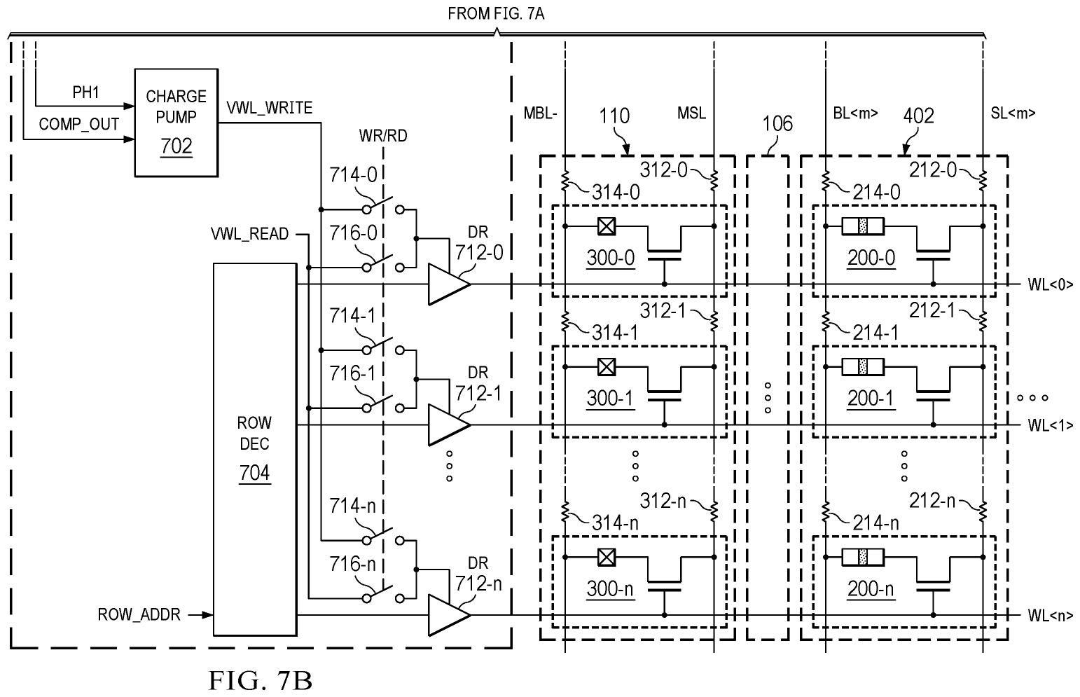

FIGS. 7A and 7B are a circuit diagram of a portion of the memory block 600 of FIG. 6 according to some examples. A memory column 402 is shown as a portion of the memory array 104. The remainder of the memory array 104 and other corresponding circuits are understood from the illustrated portion. The memory column 402 is a periphery column of the memory array 104 and corresponds with BL<m> and SL<m>. A dummy column 106 and a mimic column 110 are along the memory column 402, with the dummy column 106 between the memory column 402 and the mimic column 110. The memory column 402, dummy column 106, and mimic column 110 are as described above with respect to FIGS. 4A and 4B.

The SEL/DEC<m> 124-m is electrically connected to the SL<m> and BL<m>. The SEL/DEC<m> 124-m includes switches 408, 410, 412, 414, 416, 418. The SEL/DEC<m> 124-m is configured to selectively apply the voltage of the VDD or the voltage of the VSS to the SL<m> and to selectively apply the voltage of the VDD or the voltage of the VSS to the BL<m>, similar to described above with respect to FIGS. 4A and 4B. The switches 408-418 are electrically connected as described above with respect to FIGS. 4A and 4B, except that the respective first terminals of the switches 408, 410 are electrically connected to the VDD. The switches 408-414 are controlled by a signal on a WR_VAL<m>, and the switches 416, 418 are controlled by a signal on a WR_EN<m>, like described above with respect to FIGS. 4A and 4B.

When the SEL/DEC<m> 124-m selectively electrically connects the VDD to one of the SL<m> or the BL<m>, the SEL/DEC<m> 124-m selectively electrically connects the VSS to the other of the SL<m> or the BL<m>. The signal on the WR_EN<m> controls whether writing of an MRAM cell 200 in the memory column 402 is enabled. If not enabled, the signal on the WR_EN<m> causes both switches 416, 418 to be in an opened state, which de-couples the voltages on the VDD and VSS from the SL<m> and the BL<m>. If enabled, the signal on the WR_EN<m> causes both switches 416, 418 to be in a closed state, which may electrically connect the VDD to the SL<m> and the VSS to the BL<m> or vice versa depending on the states of the switches 408-414. The signal on the WR_VAL<m> controls which voltage is to be applied to the SL<m> and BL<m>, and hence, whether a logical “0” or “1” is to be written to an MRAM cell 200. When one of the switches 408, 412 is in a closed state, the other is in an open state, and both switches 408, 412 may be in an open state simultaneously. When one of the switches 410, 414 is in a closed state, the other is in an open state, and both switches 410, 414 may be in an open state simultaneously. When one of the switches 408, 410 is in a closed state, the other is in an open state, and both switches 408, 410 may be in an open state simultaneously. When one of the switches 412, 414 is in a closed state, the other is in an open state, and both switches 412, 414 may be in an open state simultaneously. Generally, the switches 408, 414 may be in closed states simultaneously, which may electrically connect the VDD to the SL<m> and the VSS to the BL<m> for writing a logical “1”. Generally, the switches 410, 412 may be in closed states simultaneously, which may electrically connect the VDD to the BL<m> and the VSS to the SL<m> for writing a logical “0”.

A MSEL/MDEC 114 is electrically connected to the MSL and a first terminal of the MBL (MBL+). The MSEL/MDEC 114 includes switches 424, 426, 428, 430, 432, 434. The MSEL/MDEC 114 is configured to selectively apply a voltage on the VDD or the voltage of the VSS to the MSL and to selectively apply the voltage on the VDD or the voltage of the VSS to the MBL+. The switches 424-434 are electrically connected as described above, except that respective first terminals of the switches 424, 426 are electrically connected to the VDD. The switches 424-430 are controlled by a signal on a WR_VALM, and the switches 432, 434 are controlled by a signal on a WR_ENM. The signals on the WR_VALM and the WR_ENM control the switches 424-434 to be selectively opened or closed.

When the MSEL/MDEC 114 selectively electrically connects the VDD to one of the MSL or the MBL+, the MSEL/MDEC 114 selectively electrically connects the VSS to the other of the MSL or the MBL+. The signal on the WR_ENM controls whether write calibration using the mimic column 110 is enabled. If not enabled, the signal on the WR_ENM causes both switches 432, 434 to be in an opened state, which de-couples the voltages on the VDD and VSS from the MSL and the MBL+. If enabled, the signal on the WR_ENM causes both switches 432, 434 to be in a closed state, which may electrically connect the VDD to the MSL and the VSS to the MBL+ or vice versa depending on the states of the switches 424-430. The signal on the WR_VALM controls which voltage is to be applied to the MSL and MBL+. When one of the switches 424, 428 is in a closed state, the other is in an open state, and both switches 424, 428 may be in an open state simultaneously. When one of the switches 426, 430 is in a closed state, the other is in an open state, and both switches 426, 430 may be in an open state simultaneously. When one of the switches 424, 426 is in a closed state, the other is in an open state, and both switches 424, 426 may be in an open state simultaneously. When one of the switches 428, 430 is in a closed state, the other is in an open state, and both switches 428, 430 may be in an open state simultaneously. Generally, the switches 424, 430 may be in closed states simultaneously, which may electrically connect the VDD to the MSL and the VSS to the MBL+. Generally, the switches 426, 428 may be in closed states simultaneously, which may electrically connect the VDD to the MBL+ and the VSS to the MSL.

A mimic resistor 436 is electrically connected between the MBL+ and a second terminal of the MBL (MBL−), as described above. Generally, the mimic column 110 and MSEL/MDEC 114 replicate the electrical paths from the VDD to the VSS in the memory columns and SEL/DECs 124 in the memory array 104, similar to described above.

Respective input nodes of a AMUX1 460 are electrically connected to the MBL+ and MBL−, and hence, a voltage drop across the mimic resistor 436 is input to the AMUX1 460. The AMUX1 460, capacitors 462, 472, AMUX2 464, switches 470, 474, and comparator 466 are electrically connected as described above with respect to FIGS. 4A and 4B. The COMP_OUT of the comparator 466 is electrically connected to an input node of a charge pump 702. The AMUX1 460, AMUX2 464 and switches 470, 474 are controlled by sampling logic 468, as described above.

The output signal on the COMP_OUT from the comparator 466 is input on the input node of the charge pump 702. The charge pump 702 increases or decreases a voltage on a WL write voltage node (VWL_WRITE) based on the output signal on the COMP_OUT and when triggered by a clock signal on the PH1 of the oscillator 476. The oscillator 476 is configured to generate and output the clock signals on the PH1, PH2, PH3 when the signal on the WR_ENM indicates that write calibration is enabled, as described above.

Driver circuits 712-0, 712-1, . . . , 712-n have output nodes that are electrically connected to respective WL<0>, WL<1>, WL<n> and have input nodes that are electrically connected to respective output nodes of a row decoder 704. The driver circuits 712-0, 712-1, . . . , 712-n may include or be, for example, buffer circuits. The row decoder 704 has input nodes electrically connected to the ROW_ADDR. The row decoder 704 is configured to receive a row address on the ROW_ADDR and to decode the row address to determine which WL to assert for write calibration and writing. For example, to assert a WL, the row decoder 704 outputs a logical “1” on the output node of the row decoder 704 that is electrically connected to the driver circuit that is further electrically connected to the WL to be asserted.

Positive supply nodes of the driver circuits 712-0, 712-1, . . . , 712-n are electrically connected to first terminals of respective switches 714-0, 714-1, . . . , 714-n and to first terminals of respective switches 716-0, 716-1, . . . , 716-n. Second terminals of the switches 714-0, 714-1, . . . , 714-n are electrically connected to the VWL_WRITE, which is an output node of the charge pump 702. Second terminals of the switches 716-0, 716-1, . . . , 716-n are electrically connected to the VWL_READ. The switches 714-0, 714-1, . . . , 714-n and switches 716-0, 716-1, . . . , 716-n are controlled by a signal on the WR/RD. When the signal on the WR/RD indicates a write operation is to be performed, the switches 714-0, 714-1, . . . , 714-n are in a closed state, and the switches 716-0, 716-1, . . . , 716-n are in an open state. Hence, in such circumstances, the voltage on the VWL_WRITE, as generated by the charge pump 702, is applied to the positive supply nodes of the driver circuits 712-0, 712-1, . . . , 712-n. When the signal on the WR/RD indicates a read operation is to be performed, the switches 714-0, 714-1, . . . , 714-n are in an open state, and the switches 716-0, 716-1, . . . , 716-n are in a closed state. Hence, in such circumstances, the voltage on the VWL_READ is applied to the positive supply nodes of the driver circuits 712-0, 712-1, . . . , 712-n.

Accordingly, in a write operation, the voltage on a WL to be asserted is the voltage of the VWL_WRITE, and the voltage on a WL that is not to be asserted is a voltage of, e.g., the VSS and/or a ground node. The charge pump 702 generates the voltage of the VWL_WRITE that causes the voltage drop across the mimic resistor 436 to be greater than the voltage on the VREF. Varying the voltage on VWL_WRITE causes the voltage on a WL to be varied when asserted. Varying the voltage on a WL when asserted varies the gate-to-source voltage of the access transistors 202, 302 electrically connected to that WL, which varies the drain-to-source resistance (R_{DS}) of those access transistors 202, 302. Increasing the voltage on VWL_WRITE and corresponding asserted WL decreases the drain-to-source resistance (R_{DS}) of the access transistors 202, 302. Decreasing the voltage on VWL_WRITE and corresponding asserted WL increases the drain-to-source resistance (R_{DS}) of the access transistors 202, 302. Varying the drain-to-source resistance (R_{DS}) of an access transistor varies the write current through a corresponding memory element. A reduced drain-to-source resistance (R_{DS}) increases the write current, and an increased drain-to-source resistance (R_{DS}) decreases the write current.

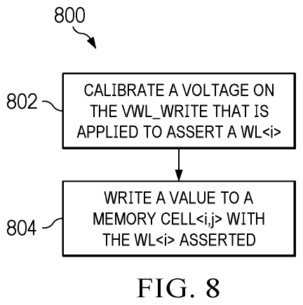

FIG. 8 is a flowchart of a method 800 for performing a write operation on a memory cell (e.g., MRAM cell 200) according to some examples. The method 800 is performed using the memory block 600 of FIGS. 6, 7A, and 7B. The method 800 may be performed for writing an MRAM cell 200 at row i and column j (designated MRAM cell 200-i,j), which is electrically connected to WL<i>, SL<j>, and BL<j>. The method 800 may be performed for simultaneously writing multiple memory cells in a same row that are to be written a same value. The method 800 may be performed iteratively for writing memory cells in a same row of the memory array with different values.

At block 802 of FIG. 8, a voltage on the VWL_WRITE is calibrated, and the voltage on the VWL_WRITE is applied to assert a WL<i>. To enter calibration, the signal on the WR_ENM transitions from not enabled to enabled. The signals on the WR_EN<0:m> remain not enabled during the calibration. The signal on the WR_ENM being enabled causes the switches 432, 434 to be closed. The signal on the WR_VALM is set to be the same as the signal on the WR_VAL<j> when writing the MRAM cell 200-i,j. If the signal on the WR_VALM corresponds to writing a logical “1”, the switches 424, 430 are closed, and switches 426, 428 are open. This electrically connects the VDD to the MSL and the VSS to the MBL. If the signal on the WR_VALM corresponds to writing a logical “0”, the switches 426, 428 are closed, and switches 424, 430 are open. This electrically connects the VSS to the MSL and the VDD to the MBL.

The row decoder 704 receives a row address on ROW_ADDR and decodes the row address to assert WL<i>. The row decoder 704 outputs a logical “1” on the output node of the row decoder 704 corresponding to WL<i>. The signal on the WR/RD indicates a write operation such that the switches 714-0, 714-1, . . . , 714-n are closed, while the switches 716-0, 716-1, . . . , 716-n are open. The driver circuit 712-i drives the voltage on the WL<i> to the voltage on the VWL_WRITE, which turns on the access transistor 302 in the mimic cell 300-i and causes a current path from the VDD to the VSS. The current path is through the MSL and MBL (with corresponding parasitic resistances 312, 314), the access transistor 302 and shorting element (e.g., metal via 304) of the mimic cell 300-i, and the mimic resistor 436. The current path causes a voltage drop across the mimic resistor 436.

The signal on the WR_ENM being enabled causes the oscillator 476 to generate respective clock signals on the PH1, PH2, and PH3. The sampling logic 468 causes the AMUX1 460 to electrically connect the MBL+ and MBL− to the terminals of the capacitor 462 during a charging phase based on the clock signal on the PH3. The capacitor 462 is charged to the voltage drop across the mimic resistor 436 (e.g., V_{MBL+}-V_{MBL-}) During the charging phase, the sampling logic 468 causes the AMUX2 464 to de-couple the capacitor 462 from the comparator 466 and the ground node connected to the AMUX2 464. Further, during the charging phase, the sampling logic 468 causes the switch 474 to be open and the switch 470 to be closed, which charges the capacitor 472 to the voltage on the VREF and de-couples the capacitor 472 from the comparator 466. The capacitor 472 is charged to the voltage on the VREF.

Then, in a pass-through phase based on the clock signal on the PH3, the sampling logic 468 causes the AMUX1 460 to be in an open state to de-couple the capacitor 462 from the mimic resistor 436, and the sampling logic 468 causes the AMUX2 464 to electrically connect the capacitor 462 to the first input node of the comparator 466. The sampling logic 468 causes the AMUX2 464 to be in a first or second closed state based on the signal on the WR_VALM. If the signal on the WR_VALM corresponds to writing a logical “0”, the sampling logic 468 causes the AMUX2 464 to be in a first closed state that applies +(V_{MBL+}-V_{MBL-}) to the first input of the comparator 466. If the signal on the WR_VALM corresponds to writing a logical “1”, the sampling logic 468 causes the AMUX2 464 to be in a second closed state that applies −(V_{MBL+}-V_{MBL-}) to the first input of the comparator 466. Further, in the pass-through phase, the sampling logic 468 causes the switch 470 to be open and the switch 474 to be closed, which electrically connects the capacitor 472 to the second input node of the comparator 466 and de-couples the capacitor 472 from the VREF.

During the pass-through phase, the comparator 466 compares the voltages on the input nodes of the comparator 466 when triggered by the clock signal on the PH2. The signal on the COMP_OUT is a logical “1” when the voltage on the first input node (electrically connected to the AMUX2 464) is greater than the voltage on the second input node (e.g., the capacitor 472). The signal on the COMP_OUT is a logical “0” when the voltage on the first input node (electrically connected to the AMUX2 464) is less than the voltage on the second input node (e.g., the capacitor 472). Due to the switching by the AMUX2 464 between the first closed state and the second closed state, more generally, the signal on the COMP_OUT is a logical “0” when the magnitude of the voltage drop across the mimic resistor 436 (as charged on the capacitor 462) is less than the voltage on VREF (as charged on the capacitor 472), and the signal on the COMP_OUT is a logical “1” when the magnitude of the voltage drop across the mimic resistor 436 (as charged on the capacitor 462) is greater than the voltage on VREF (as charged on the capacitor 472).

In the illustrated example, the charge pump 702 decreases the voltage on the VWL_WRITE when triggered by the clock signal on the PH1 and the signal on the COMP_OUT is a logical “1” and increases the voltage on the VWL_WRITE when triggered by the clock signal on the PH1 and the signal on the COMP_OUT is a logical “0.” The changing of the voltage on the VWL_WRITE changes the voltage on the WL<i> and the gate-to-source voltage (V_{GS}) of the access transistor 302 of the mimic cell 300-i, which changes the voltage drop on the mimic resistor 436. The calibration process is therefore based on a feedback loop. The calibration process may continue until, for example, the voltage on the VWL_WRITE converges. Converging a voltage permits the charge pump 702 to generate a voltage that causes the voltage on the WL<i> to be the lowest achievable voltage that permits the voltage drop on the mimic resistor 436 to be greater than the target write voltage (e.g., on the VREF). The signal on WR_ENM may indicate that write calibration is not enabled when the calibration process concludes. The signal on WR_ENM indicating that write calibration is not enabled causes the oscillator 476 to stop generating clock signals on the PH1, PH2, and PH3, which disables the sampling logic 468, the comparator 466, and the charge pump 702. The signal on WR_ENM indicating that write calibration is not enabled also causes the switches 432, 434 to be in open states de-coupling the VDD and VSS from the MSL and MBL.

Referring to block 804 of FIG. 8, a value is written to the MRAM cell 200-i,j using the WL<i> asserted. To write the MRAM cell 200-i,j, the signal on the WR_EN<j> transitions from not enabled to enabled. The signal on the WR_EN<j> being enabled causes the switches 416, 418 to be closed. The signal on the WR_VAL<j> is set for writing the MRAM cell 200-i,j. If the signal on the WR_VAL<j> corresponds to writing a logical “1”, the switches 408, 414 are closed, and switches 410, 412 are open. This electrically connects the VDD to the SL<j> and the VSS to the BL<j>. If the signal on the WR_VAL<j> corresponds to writing a logical “0”, the switches 410, 412 are closed, and switches 408, 414 are open. This electrically connects the VSS to the SL<j> and the VDD to the BL<j>. The signal on the WL<i> is asserted to turn on the access transistor 202 in the MRAM cell 200-i,j, which causes a current path from the VDD to the VSS through the MRAM cell 200-i,j. The current path is through the SL<j> and BL<j> (with corresponding parasitic resistances 212, 214) and the access transistor 202 and memory element (e.g., MTJ 204) of the MRAM cell 200-i,j. The current path causes the memory element (e.g., MTJ 204) to be written.

Some examples may be embodied as an intellectual property (IP) core (e.g., a digital or electronic representation) stored in a non-transitory storage medium (e.g., memory). For example, a circuit design including a memory block 100, 600 may be embodied as an IP core stored in a non-transitory storage medium. The IP core may be implemented as a netlist, a circuit schematic, or other representation. A user may be provided access to the IP core stored in the non-transitory storage medium. The user can incorporate the IP core into a user design with or without modification to the IP core. For example, a user may download or otherwise obtain the IP core (including the circuit design including the memory block 100, 600) onto a computing system that implements an electronic design automation (EDA) environment, and may incorporate the IP core into another circuit design using the EDA environment. Examples of a non-transitory storage medium include random access memory (RAM) (e.g., static RAM (SRAM) and dynamic RAM (DRAM)), read only memory (ROM), programmable ROM (PROM), erasable programmable ROM (EPROM), electrically erasable programmable ROM (EEPROM), flash, NAND memory, CD-ROM, an optical storage device, a magnetic storage device, etc. The non-transitory storage medium, in some examples, may be standalone memory, and may be included in any computing system (e.g., a desktop computer, a laptop computer, a server, a database, etc.).

An example is a circuit. The circuit includes a memory array, a mimic column, a mimic resistor, and a calibration circuit. The mimic column is along a periphery of the memory array. The mimic resistor is in a path through the mimic column. The calibration circuit is configured to calibrate a voltage for writing a memory cell in the memory array. The calibration circuit is electrically connected to the mimic resistor.

Another example is a method. A voltage is calibrated using a mimic column. The mimic column is along a periphery of a memory array. A value is written to a memory cell of the memory array using the calibrated voltage.

A further example is a non-transitory storage medium storing an electronic representation of a circuit design. The circuit design includes a memory block circuit. The memory block circuit includes a memory array, a mimic column, a mimic resistor, and a calibration circuit. The mimic column is along a periphery of the memory array. The mimic resistor is in a path through the mimic column. The calibration circuit is configured to calibrate a voltage for writing a memory cell in the memory array. The calibration circuit is electrically connected to the mimic resistor.

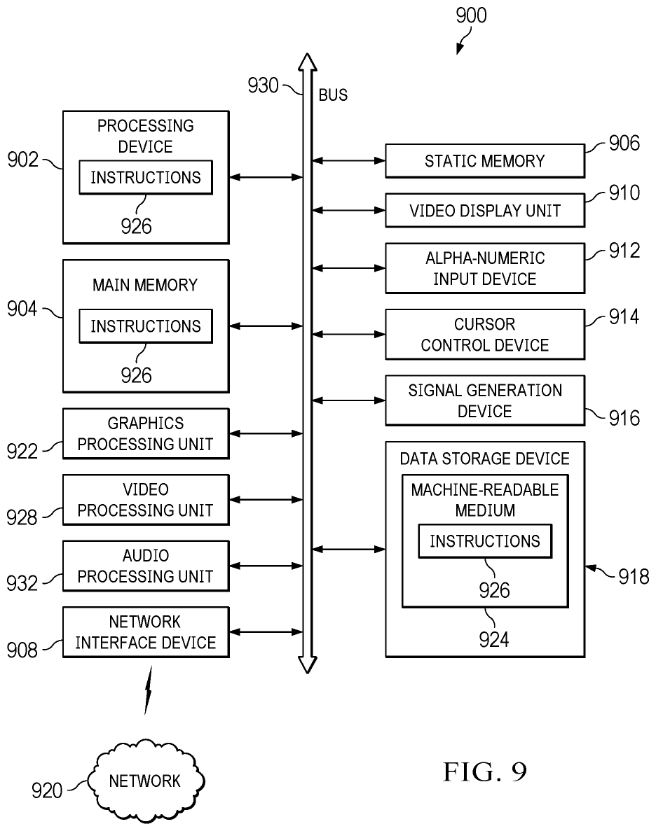

A storage subsystem of a computer system (such as computer system 900 of FIG. 9) may be used to store data structures that are used by EDA products that may implement some examples described herein (e.g., IP cores).

FIG. 9 illustrates an example machine of a computer system 900 within which a set of instructions, for causing the machine to perform any one or more of the methodologies implementing examples described herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 900 includes a processing device 902, a main memory 904 (e.g., read-only memory (ROM), flash memory, dynamic random access memory (DRAM) such as synchronous DRAM (SDRAM), a static memory 906 (e.g., flash memory, static random access memory (SRAM), etc.), and a data storage device 918, which communicate with each other via a bus 930.

Processing device 902 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 902 may also be one or more special-purpose processing devices such as an application specific integrated circuit (ASIC), a field programmable gate array (FPGA), a digital signal processor (DSP), network processor, or the like. The processing device 902 may be configured to execute instructions 926 for performing operations and steps for implementing examples in a circuit design.

The computer system 900 may further include a network interface device 908 to communicate over the network 920. The computer system 900 also may include a video display unit 910 (e.g., a liquid crystal display (LCD) or a cathode ray tube (CRT)), an alphanumeric input device 912 (e.g., a keyboard), a cursor control device 914 (e.g., a mouse), a graphics processing unit 922, a signal generation device 916 (e.g., a speaker), graphics processing unit 922, video processing unit 928, and audio processing unit 932.

The data storage device 918 may include a machine-readable storage medium 924 (also known as a non-transitory computer-readable storage medium) on which is stored one or more sets of instructions 926 or software embodying methodologies or functions for implementing examples described herein in a circuit design. The instructions 926 may also reside, completely or at least partially, within the main memory 904 and/or within the processing device 902 during execution thereof by the computer system 900, the main memory 904 and the processing device 902 also constituting machine-readable storage media.

In some implementations, the instructions 926 include instructions to implement functionality. While the machine-readable storage medium 924 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 902 to perform any methodology for implementing examples described herein. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a non-transitory computer-readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable storage medium having stored thereon instructions, which may be used to program a computer system (or other electronic devices) to perform a process according to the present disclosure. A machine-readable storage medium includes any mechanism for storing information in a form readable by a machine (e.g., a computer). For example, a machine-readable (e.g., a computer-readable) storage medium includes a machine-readable (e.g., a computer-readable) storage medium such as a read only memory (ROM), random access memory (RAM), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A circuit comprising:
a memory array;
a mimic column along a periphery of the memory array;
a mimic resistor in a path through the mimic column; and
a calibration circuit configured to calibrate a voltage for writing a memory cell in the memory array, the calibration circuit being electrically connected to the mimic resistor.

2. The circuit of claim 1, further comprising a dummy column between the memory array and the mimic column.

3. The circuit of claim 1, further comprising a first number of word lines, wherein:
the memory array includes memory cells arranged in the first number of rows and a second number of columns;
the mimic column includes the first number of mimic cells; and
a word line of the word lines is electrically connected to memory cells of the memory array and a mimic cell of the mimic column in a respective row.

4. The circuit of claim 3, further comprising:
the second number of source lines and the second number of bit lines, wherein a source line of the second number of the source lines is electrically connected to memory cells of the memory array in a respective column, and a bit line of the second number of the bit lines is electrically connected to the memory cells of the memory array in the respective column; and
a mimic source line and a mimic bit line, wherein the mimic source line is electrically connected to the mimic cells of the mimic column, and the mimic bit line is electrically connected to the mimic cells of the mimic column.

5. The circuit of claim 4, wherein the mimic resistor is in the mimic bit line.

6. The circuit of claim 4, wherein the mimic resistor is in the mimic source line.

7. The circuit of claim 1, wherein:
the memory array includes memory cells, the memory cells including the memory cell, the memory cell including:
a first access transistor having a first source/drain node, a second source/drain node, and a first gate node, the first source/drain node being electrically connected to a source line of a column of the memory array in which the memory cell is disposed, the first gate node being electrically connected to a word line of a row of the memory array in which the memory cell is disposed; and
a magnetic tunnel junction (MTJ) having a first terminal and a second terminal, the first terminal being electrically connected to the second source/drain node, the second terminal being electrically connected to a bit line of the column of the memory array in which the memory cell is disposed; and
the mimic column includes mimic cells, a mimic cell of the mimic cells including a second access transistor having a third source/drain node, a fourth source/drain node, and a second gate node, the third source/drain node being electrically connected to a mimic source line, the second gate node being electrically connected to the word line, the fourth source/drain node being electrically connected to a mimic bit line.

8. The circuit of claim 1, wherein the voltage that is calibrated by the calibration circuit is applied to a source line or a bit line, the memory cell in the memory array being electrically connected between the source line and the bit line.

9. The circuit of claim 1, wherein the voltage that is calibrated by the calibration circuit is applied to a word line, the memory cell in the memory array being electrically connected to the word line.

10. The circuit of claim 1, wherein the calibration circuit includes:
a first analog multiplexer having a first input node, a second input node, a first output node, and a second output node, the first input node being electrically connected to a first terminal of the mimic resistor, the second input node being electrically connected to a second terminal of the mimic resistor, the first analog multiplexer being configured to selectively electrically couple the first input node to the first output node and to selectively electrically couple the second input node to the second output node;
a first capacitor having a third terminal and a fourth terminal;
a second analog multiplexer having a third input node, a fourth input node, a third output node, and a fourth output node, the first output node, the third terminal, and the third input node being electrically connected together, the second output node, the fourth terminal, and the fourth input node being electrically connected together, the second analog multiplexer being configured to selectively electrically couple the third input node to the third output node or the fourth output node and to selectively electrically couple the third input node to the third output node or the fourth output node; and
a comparator having a fifth input node and a sixth input node, the fifth input node being electrically connected to the third output node, the sixth input node being configured to receive a reference voltage.

11. The circuit of claim 10, wherein the calibration circuit further includes:
a counter having a seventh input node electrically connected to a fifth output node of the comparator, the counter being configured to increase or decrease a codeword on counter output nodes based, at least in part, on a signal on the fifth output node; and
a mimic line driver having a mimic voltage node configured to be electrically coupled to a mimic source line or a mimic bit line of the mimic column, the mimic line driver being configured to generate a voltage on the mimic voltage node based on the codeword on the counter output nodes.

12. The circuit of claim 11, further comprising line drivers, wherein:
the calibration circuit further includes a code register configured to store the codeword on the counter output nodes; and
a line driver of the line drivers has a voltage node configured to be electrically coupled to a source line or a bit line of a column of memory cells of the memory array, the mimic line driver being configured to generate a voltage on the voltage node based on the codeword stored in the codeword register.

13. The circuit of claim 10, wherein the calibration circuit further includes:
a charge pump having a seventh input node electrically connected to a fifth output node of the comparator, the charge pump being configured to increase or decrease a voltage on a word line write voltage node based, at least in part, on a signal on the fifth output node; and
word line drivers, a word line driver of the word line drivers having a sixth output node electrically connected to a word line, the word line driver having a positive supply voltage node selectively coupled to the word line write voltage node.

14. A method comprising:
calibrating a voltage using a mimic column, the mimic column being along a periphery of a memory array; and
writing a value to a memory cell of the memory array using the calibrated voltage.

15. The method of claim 14, wherein calibrating the voltage includes detecting a voltage drop across a mimic resistor, the mimic resistor being in a path through the mimic column.

16. The method of claim 14, wherein:
the memory array includes rows and columns of memory cells, the memory cells include the memory cell;
a source line and a bit line are electrically connected to memory cells in a column of the columns;
a word line is electrically connected to memory cells in a row of the rows;
the memory cell includes a first access transistor and a magnetic tunnel junction (MTJ), a first source/drain node of the first access transistor being electrically connected to the source line, a second source/drain node of the first access transistor being electrically connected to a first terminal of the MTJ, a second terminal of the MTJ being electrically connected to the bit line, a gate node of the first access transistor being electrically connected to the word line;
the mimic column includes mimic cells;
a mimic source line and a mimic bit line are electrically connected to the mimic cells; and
a mimic cell of the mimic cells includes a second access transistor, a first source/drain node of the second access transistor being electrically connected to the mimic source line, a second source/drain node of the second access transistor being electrically connected to the mimic bit line, a gate node of the second access transistor being electrically connected to the word line.

17. The method of claim 16, wherein the calibrated voltage is applied to the bit line or the source line during writing the value to the memory cell.

18. The method of claim 16, wherein the calibrated voltage is applied to the word line during writing the value to the memory cell.

19. The method of claim 16, wherein calibrating the voltage includes detecting a voltage drop across a mimic resistor, the mimic resistor being in the mimic source line or the mimic bit line, the mimic resistor having a resistance that replicates an average resistance of MTJs of the memory cells of the memory array.

20. A non-transitory storage medium storing an electronic representation of a circuit design, the circuit design including a memory block circuit, the memory block circuit comprising:
a memory array;
a mimic column along a periphery of the memory array;
a mimic resistor in a path through the mimic column; and
a calibration circuit configured to calibrate a voltage for writing a memory cell in the memory array, the calibration circuit being electrically connected to the mimic resistor.
